(19) United States
(12) Patent Application Publication
(10) Pub. No.: US 2016/0333457 A1
(43) Pub. Date: Nov. 17, 2016

(54) MASK PLATE, METHOD FOR FABRICATING THE SAME, DISPLAY PANEL AND DISPLAY DEVICE

(71) Applicant: BOE TECHNOLOGY GROUP CO., LTD., Beijing (CN)

(72) Inventors: Lifei MA, Beijing (CN); Yinan LIANG, Beijing (CN); Lujiang HUANGFU, Beijing (CN)

(73) Assignee: BOE TECHNOLOGY GROUP CO., LTD., Beijing (CN)

(21) Appl. No.: 15/150,609

(22) Filed: May 10, 2016

(30) Foreign Application Priority Data
May 13, 2015 (CN) 201510242834.8

(51) Int. Cl. C23C 14/04; B23K 26/384

(52) U.S. Cl. CPC C23C 14/042; B23K 26/384; C23C 14/24

(57) ABSTRACT

A mask plate, a method for fabricating the same, a display panel and a display device are disclosed. The mask plate includes a shielding plate having an opening; the opening is surrounded by side sections along a thickness direction of the shielding plate. The opening includes: a notch disposed at an intersecting region between at least some of the side sections and a surface of the shielding plate, wherein an area of the opening close to the surface of the shielding plate is larger than that of the opening away from the surface of the shielding plate. The notch increases an area of a marginal region of a film layer evaporated on a base substrate and increases a flatness of the marginal region, thereby decreasing the possibility of fracture of the metal film layer to be formed thereafter due to a high step and increasing a defect-free of the products.

### FIELD OF THE ART

Embodiments of the disclosure relate to the technical field of display technologies, more particularly, to a mask plate, a method for fabricating the same, a display panel and a display device.

### BACKGROUND

During the process of fabricating a display panel, an organic material or metal material is generally evaporated onto a base substrate to form a desired film layer, through a vacuum evaporation process. For example, when a mask plate is used to evaporate the film, the organic material or metal material evaporated from an evaporating source is spurted to the base substrate through an opening of the mask plate, thus forming a film layer with a homogeneous thickness in the central region but having a slight slope at the marginal region, which makes the thickness of the whole film inhomogeneous.

### SUMMARY

An embodiment of the disclosure provides a mask plate and a method for fabricating the same, a display panel and a display device.

A first aspect of the disclosure provides a mask plate comprising a shielding plate having an opening, wherein the opening is surrounded by side sections along a thickness direction of the shielding plate and comprises a notch disposed at an intersecting region between at least some of the side sections and a surface of the shielding plate, wherein an area of the opening close to the surface of the shielding plate is larger than that of the opening away from the surface of the shielding plate.

A second aspect of the disclosure provides a display panel comprising a film layer which is fabricated using the above mask plate.

A third aspect of the disclosure provides a display device comprising the display panel.

A fourth aspect of the disclosure provides a method for fabricating a mask plate. The method comprises: forming an opening on a shielding plate, wherein the opening is surrounded by side sections along a thickness direction of the shielding plate; forming a notch at an intersecting region between at least some of the side sections and a surface of the shielding plate, wherein an area of the opening close to the surface of the shielding plate is larger than that of the opening away from the surface of the shielding plate.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure. Based on the described drawings herein, those skilled in the art can obtain other drawing(s) without any inventive work.

FIG. 1 (a) schematically illustrates a top view of a mask plate;

FIG. 1 (b) schematically illustrates a partial of cross section of the mask plate of FIG. 1 (a);

FIG. 2 schematically illustrates a mask plate in accordance with an embodiment of the disclosure;

FIG. 3 schematically illustrates a cross section of any of openings in the mask plate of FIG. 2 in accordance with an embodiment of the disclosure;

FIG. 4 schematically illustrates a design principle of a notch in accordance with an embodiment of the disclosure;

FIG. 5 (a) schematically illustrates a notch having a shape of rectangle in accordance with an embodiment of the disclosure;

FIG. 5 (b) schematically illustrates a notch having a shape of triangle in accordance with an embodiment of the disclosure;

FIG. 6 (a) schematically illustrates a cross section of another notch in accordance with an embodiment of the disclosure;

FIG. 6 (b) schematically illustrates a cross section of still another notch in accordance with an embodiment of the disclosure;

FIG. 7 (a) to FIG. 7 (c) schematically illustrate three arrangements of the mask plate in accordance with an embodiment of the disclosure; and

FIG. 8 schematically illustrates a display panel in accordance with an embodiment of the disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

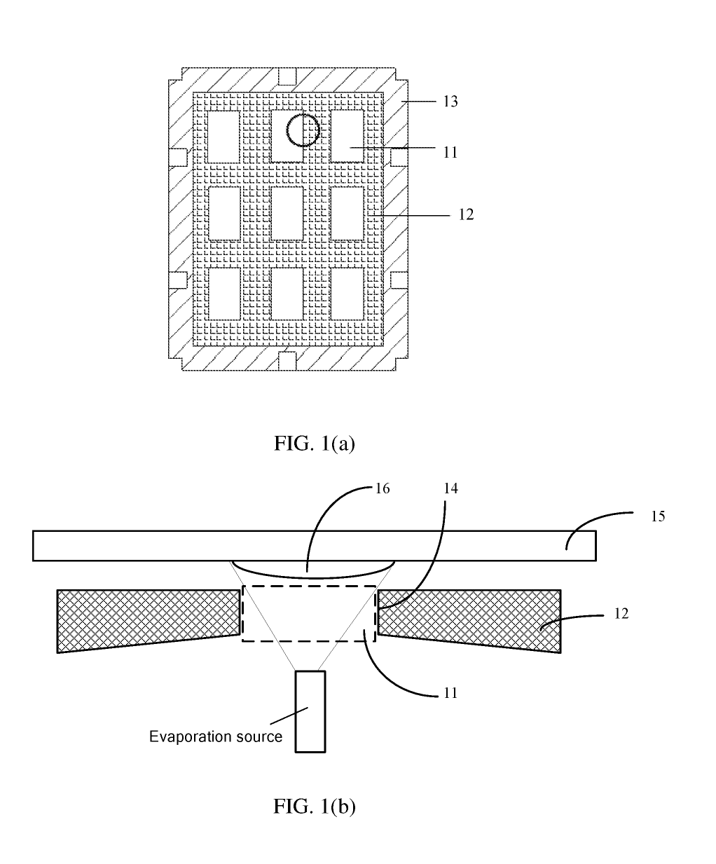

A mask plate as illustrated in FIG. 1 (a) comprises a shielding plate 12 and a plurality of openings 11. An evaporating source is heated at a high temperature in a vacuum chamber, thereby allowing an organic material or a metal material to be evaporated onto a base substrate 15 through the openings 11 to form a film layer. As illustrated in FIG. 1 (b), the openings 11 are surrounded by side sections 14. During an actual evaporation and deposition processes, the organic material or metal material evaporated from the evaporating source spurts radially. A thickness of the central region of a film layer 16 which is formed on the base substrate 15 through deposition is relatively homogeneous. However, there is a slope similar to a step in the marginal region, which has a thickness of approximately 2000 Å to 3000 Å. Other film layers formed on the film layer 16 thereafter may break due to the slope.

An embodiment of the disclosure provides a mask plate having an opening, wherein the opening is surrounded by side sections along a thickness direction of the shielding plate. The opening further comprises: a notch disposed at an intersecting region between at least some of the side sections and a surface of the shielding plate, wherein an area of the opening close to the surface of the shielding plate is larger than that of the opening away from the surface of the shielding plate.

Due to the above configuration, when a film is evaporated on a base substrate using the mask plate, an area of the opening close to the base substrate is larger than that of the opening away from the base substrate, which increases an area of a marginal region of the film formed on the base substrate and increases the flatness of the marginal region, thereby preventing the possibility of fracture of other films formed on the film thereafter such as a metal film due to a high step and increasing a defect-free of the products.

FIG. 2 schematically illustrates a mask plate in accordance with an embodiment of the disclosure. The mask plate 2 comprises:

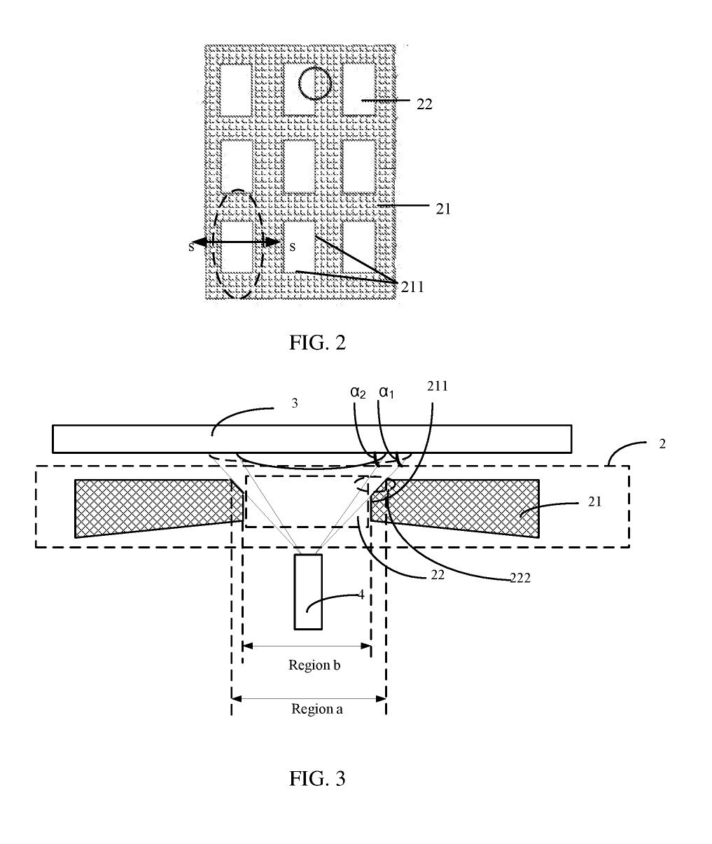

a shielding plate 21, wherein a plurality of openings 22 is distributed on the shielding plate 21 and each of the openings 22 is surrounded by side sections 211 along a thickness direction of the shielding plate (i.e., vertical direction). FIG. 3 schematically illustrates a partial cross section of the opening 22 along s-s direction of the mask plate in FIG. 2 in accordance with an embodiment of the disclosure. A notch 222 is disposed at an intersecting region between at least some of the side sections 211 and a surface of the shielding plate which is close to the base substrate during evaporation, thereby allowing an area of the opening 22 close to the base substrate to be larger than that of the opening 22 away from the base substrate, that is, an area of an open region “a” formed by the opening 22 close to the base substrate and a notch 222 together is larger than that of an open region “b” formed by the opening 22 away from the base substrate.

The notch 222 is disposed at the intersecting region between at least some of the side sections 211 and a surface of the shielding plate which is close to the base substrate 3 during the evaporating process. That is, the notch 222 is close to the base substrate 3, thereby allowing the area of the opening 22 close to the base substrate 3 to be larger than that of the opening 22 away from the base substrate 3 during the evaporating process. As a result, the organic material or metal material evaporated from the evaporating source is deposited onto the base substrate 3 through the notch 222, and the area of the film layer deposited onto the base substrate is increased, thereby increasing the flatness of the marginal region of the film layer and alleviate the problem of fracture of the metal film layer formed thereafter caused by a poor flatness of the film layer.

Considering the fact that the size of the opening of the mask plate is designed according to a predetermined size of a panel, after the notch 222 is formed on the base substrate 3, a projected area of the opening 22 with respect to the base substrate 3 in the direction perpendicular to the base substrate still equals to a predetermined area of the opening. As an example, a maximum depth of the notch 222 is less than or equal to the minimum thickness of the shielding plate. In order to make the evaporated the organic material or metal material deposited onto the base substrate with larger amount through the notch 222, as an example, the maximum width wₘₐₓ of the opening 222 along the horizontal direction is larger than or equal to a ratio between the maximum depth hₘₐₓ of the opening 222 along the vertical direction and a tangent of the evaporation angle α corresponding to the maximum depth. The evaporation angle is an included angle between the spurting direction of the evaporated material from the evaporating source through the maximum depth of the notch and the surface of the base substrate, i.e.,

$${w}_{max} \geq \frac{{h}_{max}}{tan α} .$$

For example, as illustrated in FIG. 3, an evaporation angle corresponding to the maximum depth of the notch 222 is α1. The angle α2 is an evaporation angle corresponding to the opening 22 when the notch 222 is not formed. For illustrative purposes, a thickness of the shielding plate in a vicinity of the opening is smaller than that of other regions in the embodiment of the disclosure. However, in another embodiment of the disclosure, it also may be on the contrary, that is, the thickness of the shielding plate in a vicinity of the opening is larger than that of other regions, or the thicknesses of different regions of the shielding plate are identical to each other.

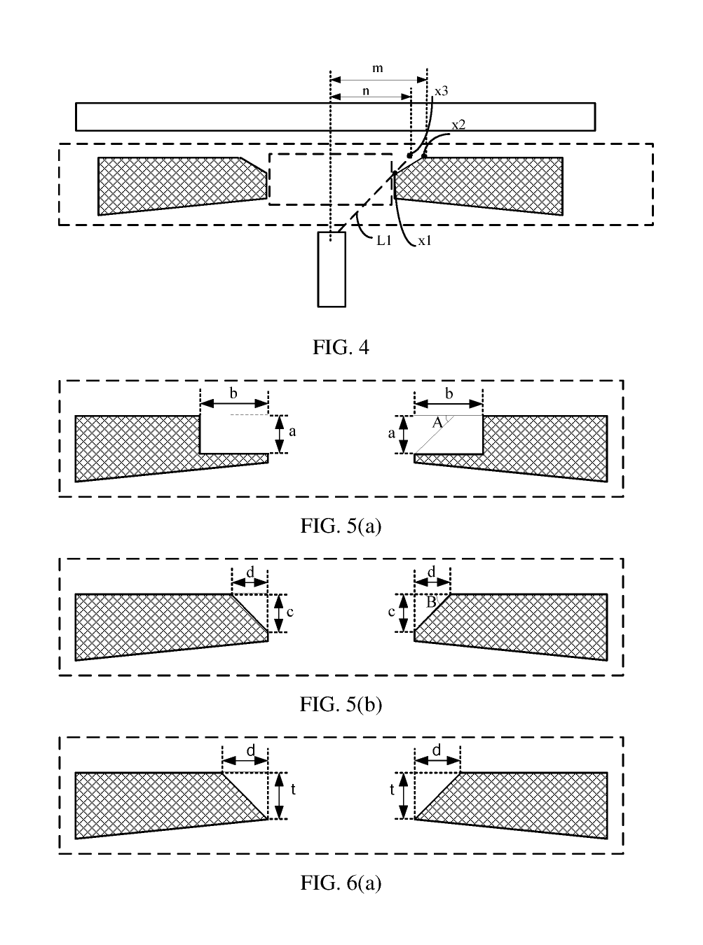

As an example, the shape of the notch is triangle or rectangle in a vertical section of the shielding plate, i.e., a cross section vertical to the plane of the shielding plate, as illustrated in FIG. 4.

The notch of the mask plate may be designed based on the following principles. As an example, the mask plate further comprises: a first reference point, a second reference point, a first elongation line and a third reference point. The first reference point is an intersection of a lower cutting line of the triangle-shaped notch and the vertical section of the shielding plate (i.e., the bottom termination point of the triangle-shaped notch). The second reference point is an intersection of an upper cutting line of the triangle-shaped notch and the vertical section of the shielding plate (i.e., the top termination point of the triangle-shaped notch). The first elongation line is extended from the straight line connecting the center of the evaporating source with the first referent point. The third reference point is an intersection of the first elongation line and the surface of the shielding plate. A straight-line distance between the second referent point and a central line of the opening is larger than or equal to a straight-line distance between the third referent point and a central line of the opening. As illustrated in FIG. 4, the first reference point of the mask plate is denoted by “x1”, the second reference point is denoted by “x2”, the first elongation line is denoted by “L1”, the third reference point is denoted by “x3”, and a vertical distance “m” between the second reference point x2 and the center line of the opening is larger than or equal to a vertical distance “n” between the third reference point “x3” and the center line of the opening.

As an example, in a cross section illustrated in FIG. 5 (a), a shape of the notch is rectangle. A depth of the notch on the base substrate along vertical direction is the width “a” of the rectangle, and a width of the notch on the base substrate along horizontal direction is the length “b” of the rectangle. As a result, in condition that the width a of the rectangular-shaped notch is set, the length b of the rectangular-shaped notch can be determined at least to be a/tanA, because an evaporation angle “A” corresponds to the depth a of the rectangular-shaped notch.

As an example, in a cross section illustrated in FIG. 5 (b), a shape of the notch is triangle, wherein the maximum depth of the notch along the vertical direction (i.e., perpendicular to the plane of the base substrate) is the length “c” of a right-angle side of the triangle, and the maximum width of the notch along the horizontal direction is the length “d” of another right-angle side of the triangle. As a result, in condition that the length c of the right-angle side of the triangle, the length d of another right-angle side of the triangle can be determined at least to be c/tanB, because an evaporation angle “B” corresponds to the length c of the right-angle side of the triangle (i.e., the maximum depth of the notch along the vertical direction).

As an example, a shape of the notch is triangle, and the maximum depth of the notch along the vertical direction is the minimum thickness of the shielding plate.

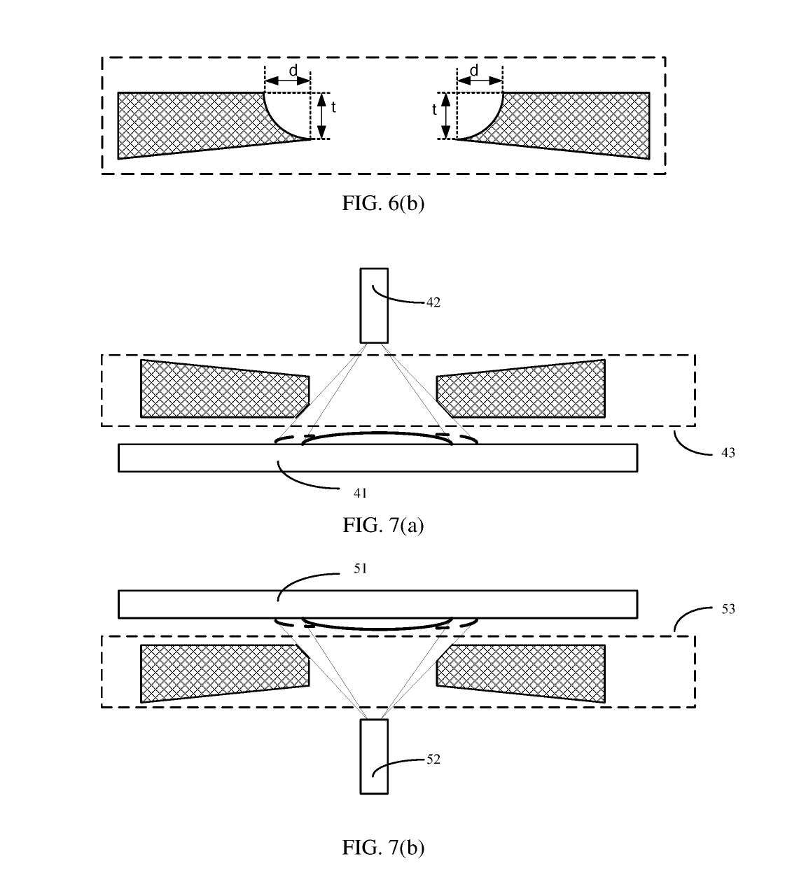

As illustrated in FIG. 6 (a), a shape of the part which is removed (i.e., the notch) is triangle. Considering the fact that a cutting depth is limited to the base substrate, the maximum depth of the notch along the vertical direction in the embodiment of the disclosure is the minimum thickness t of the shielding plate. Due to the above configuration, the notch can guarantee that all organic material or metal material in the scope of the evaporation angle corresponding to a thickness less than or equal to the minimum thickness “t” of the shielding plate pass through the notch and are deposited onto the base substrate, and can prevent the size of the opening of the mask plate from being changed, thereby preventing the compromise to the size of the panel to be formed.

It is noted that, in the embodiment of the disclosure, considering the deviation of the fabricating process, the shape of the notch of the mask plate is not exactly identical to the predetermined shape of the notch. More particularly, the vertical section of the notch may not be arranged along a straight line strictly and may be arranged along a radian illustrated in FIG. 6 (b).

As an example, a shape of the opening of the mask plate is rectangle and is surrounded by four side sections; the notch is disposed at an intersecting region between at least some of the side sections and a surface of the shielding plate close to a base substrate. The mask plate comprises the shielding plate, the shielding plate comprises a plurality of rectangular openings, and each of the openings is surrounded by the side sections along the thickness direction of the four shielding plate, wherein a size of the rectangle is determined according to a size of desired display panel. The shape of the opening may be a polygon such as a regular hexagon. As an example, the notches are disposed on each section of the six side sections which surround the opening.

As an example, the mask plate further comprises a frame. Moreover, in order to guarantee the same expand deformation, a material of the frame of the mask plate is the same with that of a shielding plate of the mask plate, such as stainless steel or ferro-nickel, which has a low thermal expansion coefficient.

As an example, a thickness of the frame of the mask plate is far larger than that of the shielding plate so as to support the mask plate during the stretching process.

It is noted that, the above mask plate may have at least three following types of arrangements during an evaporating process.

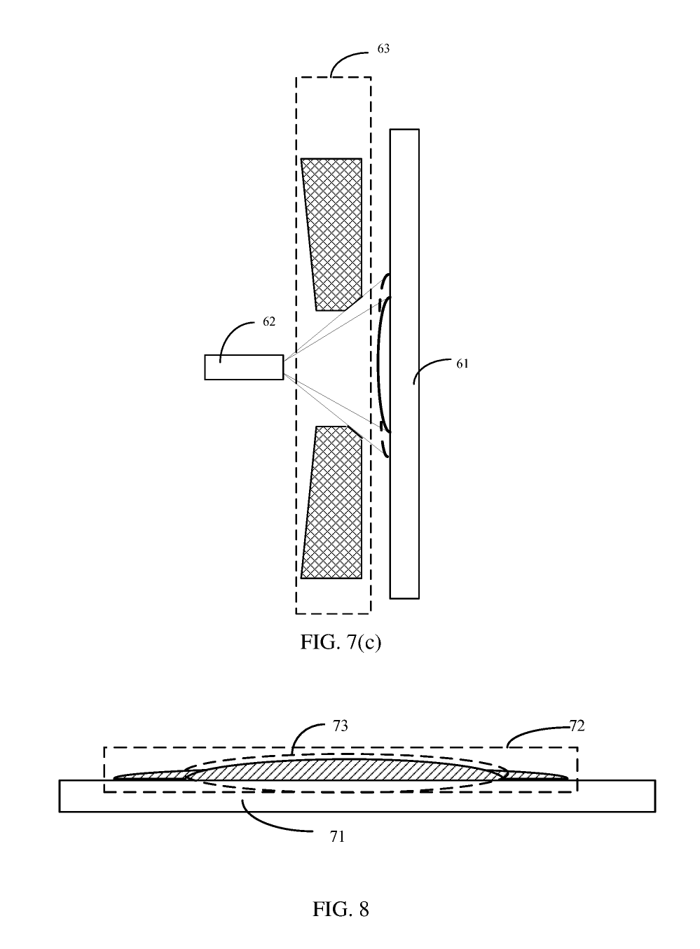

The first type: as illustrated in FIG. 7 (a), a base substrate 41 is disposed on the bottom, an evaporating source 42 is disposed on the top, a mask plate 43 is disposed between the base substrate 41 and the evaporating source 42, and the evaporating source 42 spurts organic materials or metal materials downward.

The second type: as illustrated in FIG. 7 (b), a base substrate 51 is disposed on the top, an evaporating source 52 is disposed on the bottom, a mask plate 53 is disposed between the base substrate 51 and the evaporating source 52, and the evaporating source 52 spurts organic materials or metal materials upward.

The third type: as illustrated in FIG. 7 (c), a base substrate 61 is vertically disposed, that is, the plane of the base substrate 61 is parallel to the vertical direction. An evaporating source 62 is disposed on a side of a film layer to be evaporated, a mask plate 63 is disposed between the base substrate 61 and the evaporating source 62, and the evaporating source 62 spurts organic materials or metal materials horizontally.

A display panel, more particularly an OLED display panel, which is fabricated using the mask plate of the disclosure, will be elaborated hereafter. As the structure of the mask plate of the disclosure is different from that of a conventional mask plate, a defect-free of a film layer of the display panel of the disclosure is increased, thereby increasing free-defect rate of the display panel to a certain extent and reducing fabricating cost.

FIG. 8 schematically illustrates a display panel in accordance with an embodiment of the disclosure. The display panel comprises: a base substrate 71 and a film layer 72 which is fabricated using the above mask plate. An area of the film layer 72 (i.e., an area of the region in rectangular-shaped dashed line) is larger than that of a film layer 73 (i.e., an area of the region in elliptical-shaped dashed line) which is fabricated using a mask plate having no notch disposed thereon, thereby allowing a relatively high flatness of a marginal region, and preventing the metal film layer (such as a negative pole) formed hereafter from fracturing and the broken circuit thereafter.

Moreover, the embodiment of the disclosure further provides a display device comprising the display panel. The display device is for example a mobile phone, tablet PC, a television, a display, a laptop computer, a digital photo-frame, a navigator, or any products or components with a display function.

Moreover, the embodiment of the disclosure further provides a method for fabricating a mask plate. The method comprises:

forming an opening on a shielding plate, wherein the opening is surrounded by side sections along a thickness direction of the shielding plate;

forming a notch at an intersecting region between at least some of the side sections and a surface of the shielding plate, wherein an area of a surface of the opening close to the shielding plate is larger than that of a surface of the opening away from the shielding plate.

As an example, it is possible to form a notch disposed at an intersecting region between at least some of the side sections surround the opening and the surface close to a base substrate during an evaporating process through a chemical etching process or a laser cutting process, thus allowing an area of the opening close to the base substrate to be larger than that of the opening away from the base substrate.

In all embodiments of the disclosure, through improving the mask plate, more specifically, disposing a notch at an intersecting region between at least some of the side sections and a surface close to a base substrate in each of openings of the mask plate during an evaporation process, it is possible to allow an area of the opening close to the base substrate to be larger than that of the opening away from the base substrate, thereby increasing an area of a marginal region of a film layer to be evaporated on the base substrate, increasing the flatness of the marginal region, decreasing the possibility of fracture of the metal film layer to be formed thereafter due to a too high step and increasing a defect-free rate of the products.

What is described above is related to the illustrative embodiments of the disclosure only and not limitative to the scope of the disclosure; the scopes of the disclosure are defined by the accompanying claims.

The present application claims priority from Chinese Application No. 201510242834.8 filed on May 13, 2015, the disclosure of which is hereby incorporated by reference herein in its entirety.

What is claimed is:

1. A mask plate, comprising a shielding plate which is provided with an opening, wherein the opening is surrounded by side sections along a thickness direction of the shielding plate and comprises:
a notch disposed at an intersecting region between at least some of the side sections and a surface of the shielding plate, wherein an area of the opening close to the surface of the shielding plate is larger than that of the opening away from the surface of the shielding plate.

2. The mask plate of claim 1, wherein the notch is triangle-shaped or rectangle-shaped in a cross section of the shielding plate which is perpendicular to a plane of the shielding plate.

3. The mask plate of claim 2, wherein a maximum depth of the notch along a vertical direction is smaller than or equal to a minimum thickness of the shielding plate.

4. The mask plate of claim 2, wherein a maximum width of the notch along a horizontal direction is larger than or equal to a ratio between the maximum depth of the notch along the vertical direction and a tangent of an evaporation angle corresponding to the maximum depth.

5. The mask plate of claim 1, wherein the opening is rectangle-shaped, and surrounded by four side sections, and the notch is disposed at the intersecting region between each side section and the surface of the shielding plate.

6. The mask plate of claim 1, wherein the mask plate is configured for forming a film on a base substrate, and the notch of the mask plate is close to a surface of the base substrate to have a film formed thereon during a film formation process.

7. The mask plate of claim 1, further comprising a frame, wherein a material of the frame is the same as that of the mask plate.

8. The mask plate of claim 7, wherein the material is stainless steel or ferro-nickel.

9. A display panel comprising a film layer which is fabricated using the mask plate of claim 1.

10. A display device comprising the display panel of claim 9.

11. A method for fabricating a mask plate, comprising:
forming an opening on a shielding plate, wherein the opening is surrounded by side sections along a thickness direction of the shielding plate;
forming a notch at an intersecting region between at least some of the side sections and a surface of the shielding plate, wherein an area of the opening close to the surface of the shielding plate is larger than that of the opening away from the surface of the shielding plate.

12. The method of claim 11, wherein the notch is formed through a chemical etching process.

13. The method of claim 11, wherein the notch is formed through a laser cutting process.
